(19) United States
(12) Patent Application Publication
(10) Pub. No.: US 2026/0312559 A1
(43) Pub. Date: Oct. 8, 2026

(54) AMPLIFIER GAIN CONTROL FOR CONSTANT INPUT IMPEDANCE

(71) Applicant: pSemi Corporation, San Diego, CA (US)

(72) Inventors: David KOVAC, San Diego, CA (US); Joseph GOLAT, San Diego, CA (US)

(21) Appl. No.: 19/098,243

(22) Filed: Apr. 2, 2025

(51) Int. Cl. H03G 3/30; H03F 3/16

(52) U.S. Cl. CPC H03G 3/30; H03F 3/16; H03G 2201/103; H03G 2201/106

(57) ABSTRACT

Amplifier for operation according to a plurality of gain states is presented. The amplifier includes first and second attenuation blocks that are concurrently activated during operation according to at least one gain state. Respective changes to the input impedance of the amplifier caused by the first and second attenuation blocks are in opposite directions in the Smith chart. When concurrently activated, the respective changes counteract so that the input impedance is unchanged. Activation of the first attenuation block includes coupling of a first impedance to a first terminal of a first transistor of the amplifier. Activation of the second attenuation block includes coupling of a second impedance to a second terminal of the first transistor. In one aspect, the activation of the second attenuation block includes deQing of a degeneration inductor. More than one gain state can be provided by the concurrent activation while maintaining the input impedance unchanged.

### TECHNICAL FIELD

The present application is related to electronic radio frequency (RF) circuits, and more particularly to methods and structures to control the input impedance of an amplifier across the amplifier's gain states.

### BACKGROUND

Amplifiers used in present day RF communication systems/devices, such as for example, handheld devices, may be required to support multiple gain states while operating within a specific frequency band of a plurality of supported frequency bands.

In some cases, switching between gain states may result in a variation of an input impedance of the amplifier, and therefore a mismatch of the input impedance with respect to an impedance of an upstream stage that feeds the amplifier. In turn, such mismatch may cause an error in the effective gain of the amplifier compared to an expected/designed-for gain of the amplifier.

It follows that teachings according to the present disclosure describe methods and structures for controlling of the input impedance of the amplifier while providing a desired gain of the amplifier, which can therefore be used to eliminate/reduce the above-described impedance mismatch.

### SUMMARY

According to a first aspect of the present disclosure, an amplifier circuit is presented, comprising: a first transistor; a first attenuation circuit coupled to a first terminal of the first transistor; and a second attenuation circuit coupled to a second terminal of the first transistor, wherein the first attenuation circuit, when activated, changes an input impedance of the amplifier in a first direction, wherein the second attenuation circuit, when activated, changes the input impedance of the amplifier in a second direction that is opposite the first direction, and wherein the amplifier circuit is configured for operation according to at least: a first gain state provided by concurrent activation of the first attenuation circuit and the second attenuation circuit, and a second gain state provided by concurrent deactivation of the first attenuation circuit and the second attenuation circuit, and wherein an input impedance of the amplifier remains substantially constant during operation according to the first and second gain states.

According to a second aspect of the present disclosure, a method for controlling gain of an amplifier, the method comprising: determining a target gain reduction of the amplifier relative to a high gain of the amplifier; coupling, to the amplifier, a first attenuation block configured to change an input impedance of the amplifier in a first direction; coupling, to the amplifier, a second attenuation block configured to change the input impedance of the amplifier in a second direction opposite to the first direction; allocating a first portion of the target gain reduction to the first attenuation block; allocating a second portion of the target gain reduction to the second attenuation block; activating the first attenuation block to achieve the first portion of the target gain reduction; and activating the second attenuation block to achieve the second portion of the target gain reduction, wherein changes to the input impedance caused by the first and second attenuation blocks substantially counteract each other, thereby maintaining the input impedance substantially unchanged.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a simplified schematic of a cascode amplifier.

FIG. 1B shows a simplified schematic of another cascode amplifier.

FIG. 1C shows a simplified schematic of a single device amplifier.

FIG. 2 shows various functional blocks that can be used to control the gain of an amplifier.

FIG. 3 shows the effect of an input match circuit on an input impedance of an amplifier.

FIG. 4 shows the effect of an input attenuator on an input impedance of an amplifier.

FIG. 5 shows the effect of a feedback network on an input impedance of an amplifier.

FIG. 6A shows the effect of a deQing circuit coupled in series to a degeneration inductor on an input impedance of an amplifier.

FIG. 6B shows a deQing circuit coupled in parallel to a generation inductor.

FIG. 7A shows a combination of functional blocks according to an embodiment of the present disclosure coupled to an amplifier and corresponding effect on an input impedance of the amplifier.

FIG. 7B shows another coupling arrangement of a combination of functional blocks according to an embodiment of the present disclosure coupled to an amplifier.

FIG. 8A and FIG. 8B show Smith charts representative of various methods according to the present disclosure to control input impedance of an amplifier.

FIG. 9 shows various process steps of a method according to the present disclosure.

Like reference numbers and designations in the various drawings indicate like elements.

### DETAILED DESCRIPTION

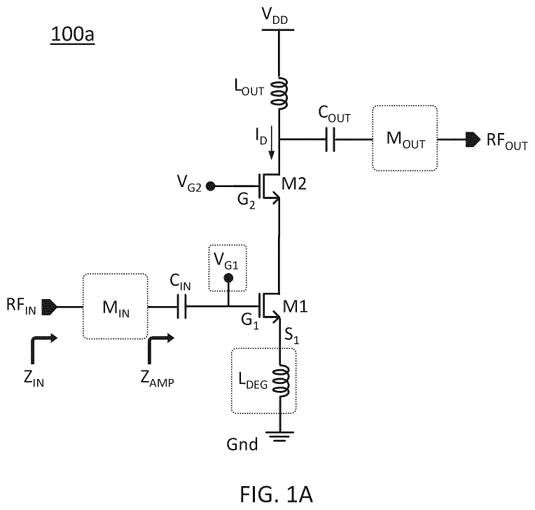

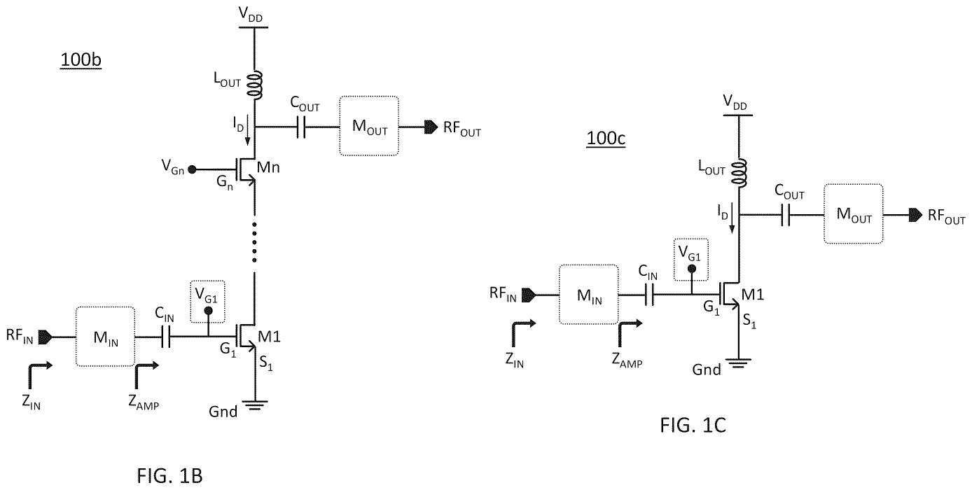

FIG. 1A shows a simplified schematic of an amplifier (100a) that may be used, for example, in a receive or transmit side of an RF system, such as, for example, an RF frontend (RFFE). In such an RF system, part of, for example, a handheld device, the amplifier (100a) may amplify an input RF signal, RF_{IN}, to the amplifier (100a) to output a corresponding amplified output RF signal, RF_{OUT}. When operating in a receive side of the RF system, the input RF signal, RF_{IN}, may be an RF signal received at an antenna and the amplifier (100a) may be referred to as a low noise amplifier (LNA), and when operating on a transmit side of the RF system, the output RF signal, RF_{OUT}, may be an RF signal transmitted at the antenna and the amplifier (100a) may be referred to as a power amplifier (PA). Teachings according to the present disclosure may equally apply to a power amplifier (PA) or a low noise amplifier (LNA).

In the exemplary case shown in FIG. 1A, processing (e.g., amplification) of the input RF signal, RF_{IN}, may be provided through a cascode configuration (M1, M2, a cascode arrangement, a cascode amplifier) comprising an input transistor (e.g., first transistor), M1, that is in series connection with an output cascode transistor, M2. A DC biasing of the cascode configuration (M1, M2) may be provided via (gate) biasing signals (V_{G1}, V_{G2}) provided/coupled (e.g., via one or more of, for example, inductor, resistor, transformer, switch, etc.) to gates of the transistors (M1, M2), in combination with a supply voltage, V_{DD}, that is coupled to a drain of the output cascode transistor, M2, through an inductor, L_{OUT}, and a reference ground, Gnd, that is coupled to a source, S1, of the input transistor, M1, through for example, an optional degeneration inductor, L_{DEG}. Such DC biasing may determine a DC biasing current, ID, that flows through the cascode configuration (M1, M2). As shown in FIG. 1A, the input transistor, M1, is configured as a common source transistor, and the output cascode transistor, M2, is configured as a common gate transistor. When configured as an LNA, the amplifier (100a) may include the degeneration inductor, L_{DEG}, and may be referred to as an inductively degenerated common source LNA.

It is noted that while FIG. 1A shows a cascode configuration using FETs comprising the input transistor (e.g., M1, first transistor) in series connection with an output cascode transistor (e.g., M2, second/last transistor), the principles described herein are applicable more broadly. The first transistor may be a FET (where the relevant terminals are gate, source and drain) or a Bipolar Junction Transistor (BJT) (where the relevant terminals are base, emitter and collector) and may be used in various amplifier configurations including common source/emitter, common gate/base, or cascode arrangements. For clarity, FET examples and terminology (e.g. M1 for the first transistor, G1 for gate/first terminal, S1 for source/second terminal) are primarily used in the figures but should be understood to encompass BJT implementations unless otherwise specified

With continued reference to FIG. 1A, the amplifier (100a) may include an input match circuit, M_{IN}, coupled to the input transistor, M1, by way of an AC coupling capacitor, C_{IN}. The input match circuit, M_{IN}, may include reactive and/or resistive elements configured to match, at an operating frequency (e.g., a frequency band of operation) of the amplifier (100a), an impedance, Z_{AMP}, presented by the (gate of the) input transistor, M1, to an impedance, Z_{IN}, seen by the input RF signal, RF_{IN}. Similarly, the amplifier (100a) may include an output match circuit, M_{OUT}, coupled to the output cascode transistor, M2, by way of an AC coupling capacitor, Cour. The output match circuit, M_{OUT}, may include reactive and/or resistive elements configured to match, at the operating frequency of the amplifier (100a), an impedance presented by the (drain of the) output cascode transistor, M2, to an impedance seen by the output RF signal, RF_{OUT}. In the present disclosure, the input impedance, Z_{AMP}, may be referred to as the input impedance to the cascode configuration/amplifier (M1, M2) or cascode input impedance, and the input impedance, Z_{IN}, may be referred to as the matched input impedance to the amplifier (100).

The amplifier (100a) may be configured to operate according to a plurality of frequency bands (e.g., frequencies of operation), and the input and/or output matching circuits, M_{IN} and/or M_{OUT}, may be selectively tuned (e.g., via adjustable/settable/programmable reactive and/or resistive elements) for operation according to each of the plurality of frequency bands. For example, the input matching circuit, M_{IN}, may be tuned such that at a given/specific (e.g., frequency range of the) frequency band, the impedance, Z_{IN}, is equal to an output impedance of an upstream stage that feeds the input RF signal, RF_{IN}, to the amplifier (100a), thereby providing efficient transfer of power (e.g., reduced return loss) between the upstream stage and the amplifier (100a).

With continued reference to FIG. 1A, when operating according to a specific/given frequency band of the plurality of frequency bands, the amplifier (100a) may be further configured to operate according to a plurality of gain states. In other words, at a given frequency band, the gain of the amplifier (100a) may be changed while the input and/or output matching circuits, M_{IN} and/or M_{IN}, are unchanged. Assuming that the input matching circuit, M_{IN}, remains unchanged across the plurality of gain states, if the impedance, Z_{AMP}, changes across (any one of) the plurality of gain states, then the impedance, Z_{IN}, also changes across the plurality of gain states, resulting in an impedance mismatch between the amplifier (100a) and the upstream stage that feeds the input RF signal, RF_{IN}, to the amplifier (100a). Such mismatch may engender different return loss performances across the plurality of gain states which may in turn engender errors in the effective gain of the amplifier (100a) compared to an expected/designed-for gain of the amplifier. In some cases, such errors in the effective gain may be substantial (e.g., 1 dB and higher) relative to preset design goals and therefore considered undesirable.

As described in more details later in the present disclosure, teachings according to the present disclosure enable control of the impedance, Z_{AMP}, and therefore of the impedance, Z_{IN}, of an amplifier (e.g., 100a of FIG. 1A), via a combination of functional blocks (e.g., circuits) that when coupled to the amplifier, further allow independent control of the gain of the amplifier. In other words, such functional blocks may allow the achievement of a target gain state and a target input impedance (e.g., Z_{AMP}, Z_{IN}) of the amplifier independently. Accordingly, teachings according to the present disclosure may allow equalization of the amplifier's input impedance across the plurality of gain states. It is noted that the independent control of the (input) impedance and the gain may require that when concurrently coupled to the amplifier, such functional blocks do not influence each other's effects, or in other words, do not interact. For example, if one of the functional blocks has the effect of increasing the input impedance (or gain) by a certain amount when coupled to the amplifier, such amount may not (substantially) change when another of the functional blocks is coupled to the amplifier.

Teachings according to the present disclosure may not be limited to the two-device cascode amplifier/configuration (e.g., amplifier 100a) of FIG. 1A. Rather, the present teachings may equally apply to a multi-device cascode amplifier (100b) as shown in FIG. 1B, and to a single-device amplifier (100c) as shown in FIG. 1C.

The multi-device cascode amplifier (100b) of FIG. 1B, may include a plurality of series connected transistors (M1, . . . , Mn, n>2), including an input transistor, M1, and a plurality (n−1) cascode transistors ( . . . , Mn, n>2) including an output cascode transistor, Mn. On the other hand, the single-device amplifier (100c) may include a single transistor, M1, configured as a common source amplifier. Further details on features/elements shown in FIG. 1B and FIG. 1C can be taken from the above description with reference to FIG. 1A, mutatis mutandis, and including, for example, replacing of the subscript “2” used in FIG. 1A with the subscript “n” used in FIG. 1B. It is noted that in the foregoing description, a two-device cascode configuration is shown/discussed, but should not be considered as limiting the scope of the present disclosure.

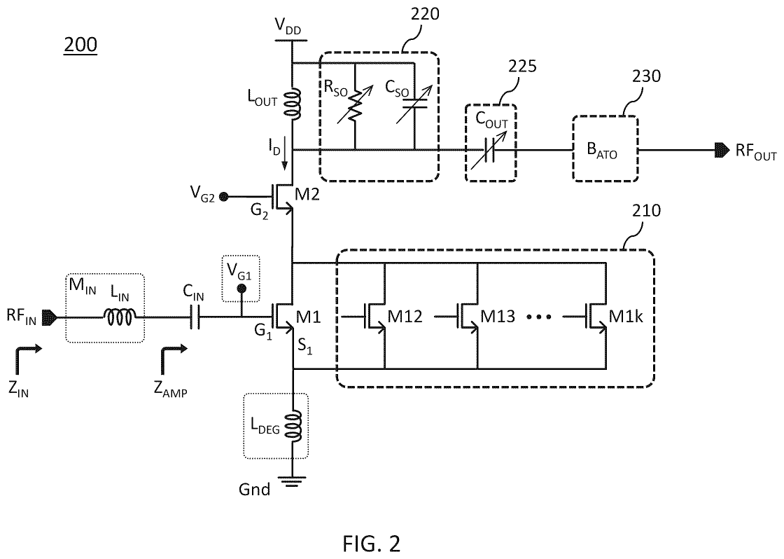

FIG. 2 shows various exemplary functional blocks (210, 220, 225, 230, e.g., gain-control circuits, blocks, handles, etc., shown in darker outlines) that can be used to control the gain of an amplifier (200) to establish predetermined gain states. Such functional blocks may be used to either increase gain (e.g., 210, amplify), or decrease/limit gain (e.g., 220, 225, 230, attenuate). In other words, such functional blocks may either increase/amplify current/voltage or decrease/attenuate current/voltage. According to some embodiments, at a given frequency band, the gain of the amplifier (e.g., 200) may include a nominal “high” (or maximum) gain that may establish a high gain state and a corresponding nominal input impedance (e.g., Z_{AMP}, Z_{IN}) of the amplifier. Accordingly, other gain states of the amplifier may be considered as having gains that are lower relative to the high gain state, or in other words, gains that are established via current/voltage attenuations.

For example, the functional block (210) shown in FIG. 2 may increase a (AC) current gain (and therefore gain of the amplifier) through the cascode configuration (M1, M2) by effectively increasing the size of the input transistor, M1, to include any one or more of the transistors (M12, M13, . . . , M1K). Accordingly, the size of the input transistor, M1, and therefore of the gain of the amplifier (200), may be increased stepwise, each step corresponding to one of the transistors (M12, M13, . . . , M1k) being coupled in parallel to the input transistor, M1, so that respective gates, sources and drains are connected (e.g., gates connected via switches, not shown in the figure). It is noted that such sizing of the input transistor, M1, via the functional block (210) may have negligible effect on the input impedance (e.g., Z_{AMP}, Z_{IN}) of the amplifier (200), especially in the presence of the (predominant) degeneration inductor, L_{DEG}.

The functional block (220) shown in FIG. 2 may decrease the gain of the amplifier by limiting the gain via, for example, a deQing resistor R_{SO}. As shown in FIG. 2, the functional block (220) may be coupled in parallel to the inductor, L_{OUT}, and includes the resistor, R_{SO}, connected in parallel to a (shunt) capacitor, C_{SO}. Accordingly, the resistor, R_{SO}, can affect the quality factor (e.g., deQing) of the inductor, L_{OUT}, thereby control (e.g., limit, decrease) the gain of the amplifier (200). By making any one or more, of the resistor, R_{SO}, the capacitor, C_{SO}, and/or the capacitor, C_{OUT}, tunable (e.g., via adjustable/settable/programmable), proper output matching to a load coupled to the output RF signal, RF_{OUT}, may be provided.

The functional block (230) shown in FIG. 2 may decrease the gain of the amplifier via one or more series connected attenuators (e.g., 230). These attenuators may be controllable (e.g., adjustable/settable/programmable, such as an RF stepped attenuator or a digital step attenuator) to provide different levels/steps of (e.g., relative) attenuations (e.g., gain<0 dB) as well as a passthrough/bypass mode (e.g., zero series impedance), and in some cases an isolation mode (e.g., high series impedance).

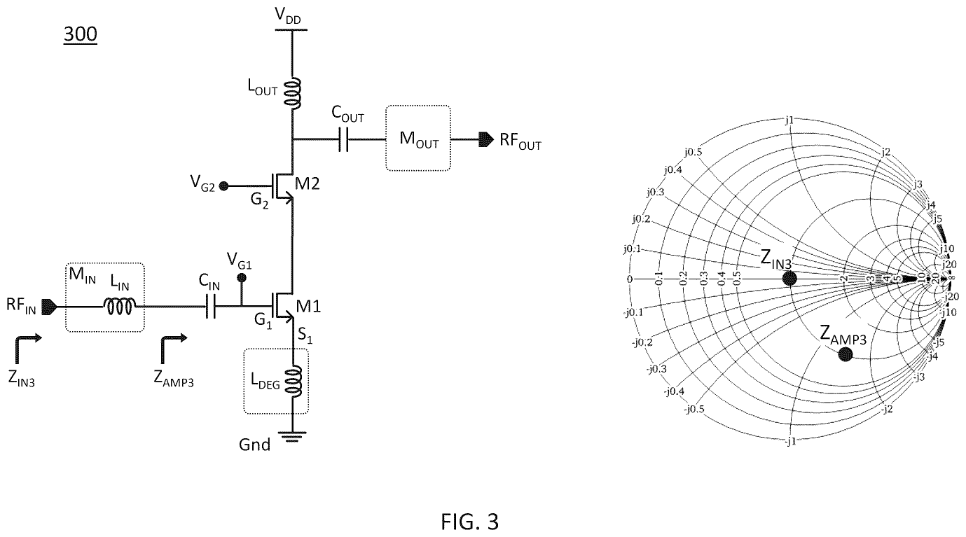

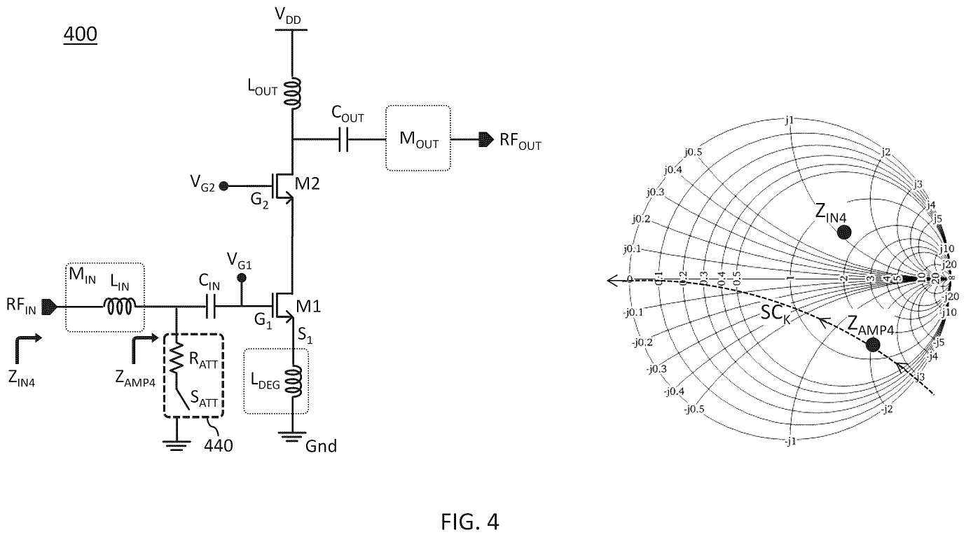

The functional blocks (210, 220, 225, 230) may affect the output impedance of the amplifier (200), but their impact on the input impedance (e.g., Z_{AMP}, Z_{IN}) of the amplifier (200) may be considered negligible/insignificant. In other words, controlling gain states of the amplifier (200) via any one or more of the functional blocks (210, 220, 225, 23) may not engender errors in gain of the amplifier based on inconsistencies/changes in return loss performance across the gain states. As described below in the present disclosure, this is not the case for the functional blocks shown in FIGS. 3-6.

FIG. 3 shows the effect of an input match, M_{IN}, on an input impedance (e.g., Z_{AMP3}, Z_{IN3}) of an amplifier (300). The amplifier (300) may be considered as equivalent to the amplifier (100a) described above with reference to FIG. 1A, wherein the input match, M_{IN}, is a series connected inductor, LIN. Effect of the input match, M_{IN}, on the input impedance is shown by way of a Smith chart that includes complex coordinates (r: real/resistive part; j: imaginary/reactive part) of the impedances, Z_{AMP3} and Z_{IN3}. As shown in the Smith chart of FIG. 3, the inductor, LIN, has the effect of rotating the impedance, Z_{AMP3}, within a constant resistance circle that passes through the prime center (r=1; j=0) of the Smith chart, resulting in the impedance, Z_{IN3}, being centered at the prime center (e.g., perfect match). In other words, the purely (positive) imaginary impedance (e.g., reactance, inductance) of the inductor, LIN, may cancel the (negative) imaginary part (e.g., reactance, capacitance) of the impedance, Z_{AMP3}, to generate the (e.g., perfectly matched) impedance, Z_{IN1}. Such a description may be performed in reverse for describing the effect of the input match, M_{IN}, on transforming the impedance, Z_{IN3}, to the impedance, Z_{AMP3}.

It is noted that implementation of the input match, M_{IN}, or in other words, elements (e.g., L, R, C) included in the input match, M_{IN}, may be based on the impedances, Z_{IN3} and Z_{AMP3}. In general, for any given impedance set, (Z_{IN3}, Z_{AMP3}), a corresponding matching circuit (e.g., M_{IN}) may be realizable. Furthermore, it is noted that although generally a perfect match may be considered as a point on the Smith chart where a characteristic/system impedance is located, such point may not exclusively coincide on the prime center (r=1; j=0) of the Smith chart. In other words, teachings according to the present disclosure may be applicable in maintaining any input impedance (e.g., Z_{IN3}) substantially constant across the various/different gain states, or at least a subset of the various/different gain states, whether a purely resistive input impedance or one that includes a reactive component.

While the functional blocks described in FIG. 2 primarily affect gain without significantly altering the input impedance of the amplifier, the functional blocks (e.g., 440, 550, 660a/b) described below with reference to FIGS. 4, 5, 6A and 6B, may concurrently affect gain and input impedance of the amplifier. However, pairing of such functional blocks to obtain a desired combined effect on the input impedance (and gain) of the amplifier may only be possible for those pairs that do not interact. For example, as described later in the present disclosure, the pair of functional blocks (440, 660a/b) may be combined for independent control of the input impedance and gain of the amplifier, whereas the pair of functional blocks (550, 660a/b) may not.

FIG. 4 shows the effect of an input attenuator (440) on an input impedance (e.g., Z_{AMP4}, Z_{IN4}) of an amplifier (400). The amplifier (400) may be considered as equivalent to the amplifier (300) described above with reference to FIG. 3, with the addition of the input attenuator (440) being coupled to the input of the amplifier. In particular, in the configuration shown in FIG. 4, the input attenuator (440) is coupled, on one side (e.g., one terminal), between the input match, M_{IN}, and the AC coupling capacitor, C_{IN}, and on the other side (e.g., other terminal), to the reference ground, Gnd. As shown in FIG. 4, the input attenuator (440) may include a resistor, R_{ATT}, that is in series connection to a switch, S_{ATT}.

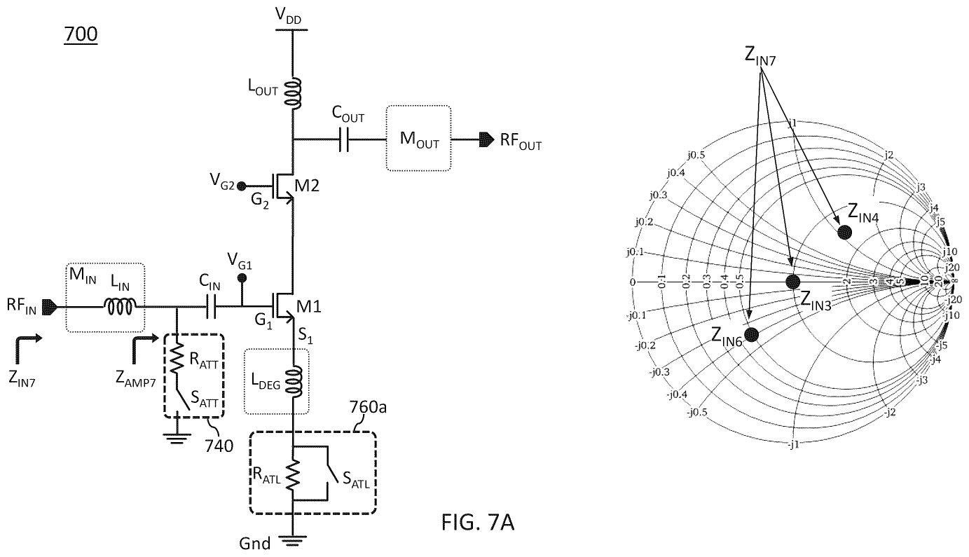

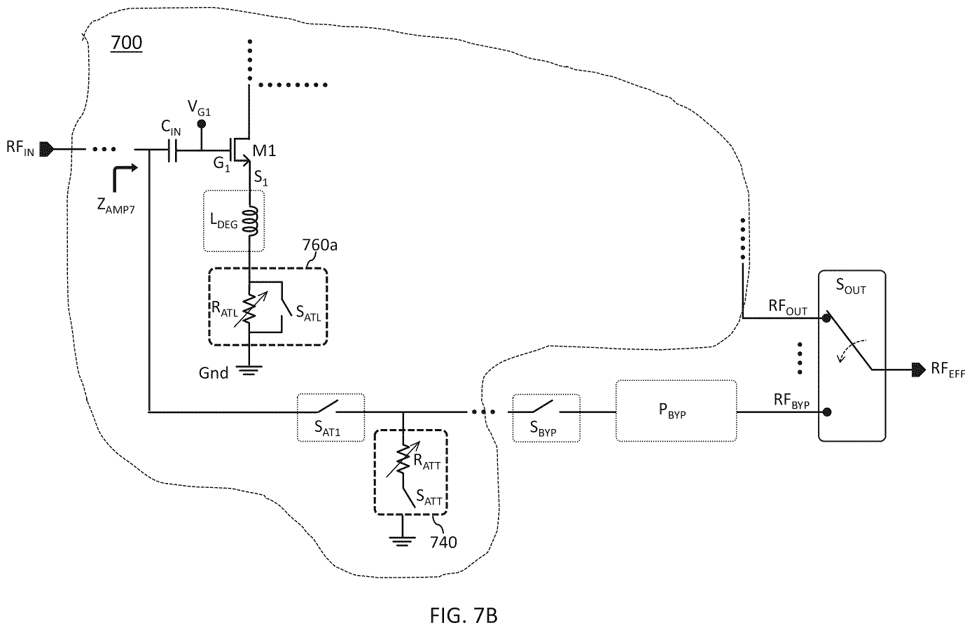

When the switch, S_{ATT}, shown in FIG. 4 is deactivated (e.g., OFF state), the switch, S_{ATT}, decouples the resistor, R_{ATT}, from the reference ground, Gnd, thereby deactivating the attenuation (i.e., unaffected amplifier gain). In this case, the input attenuator (440) may be considered deactivated and ideally have no, or negligeable/insignificant, effect on the input of the amplifier (400), and therefore on the gain. Accordingly, the input impedances (Z_{AMP4}, Z_{IN4}) of the amplifier (400) may be located according to the Smith chart described above with reference to FIG. 3. It is noted that in the practical implementation of the amplifier (400), the input attenuator (440) may have some small (loading) effect on the input of the amplifier (400). Such small effect may be reduced by either swapping the position of the resistor, R_{ATT}, with that of the switch, S_{ATT}, or by including an additional switch (e.g., S_{AT1} of FIG. 7B later described) that is coupled between the input attenuator (440) and the amplifier (400) so to further isolate the two when the attenuator is (440) deactivated.

With continued reference to FIG. 4, when the switch, S_{ATT}, is activated (e.g., ON state), the switch, S_{ATT}, shunts/couples the resistor, R_{ATT}, to the reference ground, Gnd, thereby activating the attenuation (i.e., reduce/attenuate amplifier gain). The amount of the attenuation provided by the activated input attenuator (440) may be based on the value of the (shunt) resistor, R_{ATT}. The effect of the activated input attenuator (440) on the input impedance (e.g., Z_{AMP4}, Z_{IN4}) of the amplifier (400) is shown on the Smith chart of FIG. 4. Such an effect may be considered as being relative to an input impedance (Z_{AMP4|D}, Z_{IN4|D}) of the amplifier (400) when the input attenuator (440) is deactivated, with (Z_{AMP4|D}, Z_{IN4|D})=(Z_{AMP3}, Z_{IN3}) shown in the Smith chart of FIG. 3.

As shown in the Smith chart of FIG. 4, the activated input attenuator (440), has the effect of increasing the resistance (e.g., from r=1 to r≈2) and the reactance/capacitance (e.g., from j≈−1.5 to j=−2) of the input impedance, Z_{AMP4}, when compared to, Z_{AMP3}, of FIG. 3. Accordingly, as shown in the Smith chart of FIG. 4, the inductor, LIN, used as input match, rotates the impedance, Z_{AMP4}, within the constant resistance circle of r≈2 of the Smith chart and therefore results in the impedance, Z_{IN4}, that is not centered at the prime center (e.g., not a perfect match) of the Smith chart. It is noted that inventors of the present application have observed that such an effect of the activated input attenuator (440) shown in the Smith chart of FIG. 4 of increasing the (resistance/reactance) of the input impedance, Z_{AMP4}, when compared to, Z_{AMP3}, of FIG. 3, may only be valid for a limited range of values/resistances of the (shunt) resistor, R_{ATT}. In particular, as shown in the Smith chart of FIG. 4, the increasing values of the (shunt) resistor, R_{ATT}, may move the input impedance, Z_{AMP4}, along a constant susceptance curve, SC_{K}, resulting in the input impedance, Z_{AMP4}, increasing before it starts to decrease. Accordingly, effectiveness/capability of the input attenuator (440) in increasing the input impedance may be provided by a limited range of lower values of the (shunt) resistor, R_{ATT}.

Accordingly, when activated, the input attenuator (440) of FIG. 4 may affect the gain of the amplifier (400) primarily by way of the input attenuation (shunt resistor, R_{ATT}) per se, but also by way of an undesired secondary effect that changes the input impedance (e.g., Z_{AMP4}, Z_{IN4}), thereby causing a mismatch between the input impedance (e.g., Z_{IN4}) with respect to an impedance of an upstream stage that feeds the amplifier (400). It is noted that as previously described in the present disclosure, the input matching (e.g., M_{IN}) may be assumed fixed since it may not be available for tuning when operating within a same frequency band.

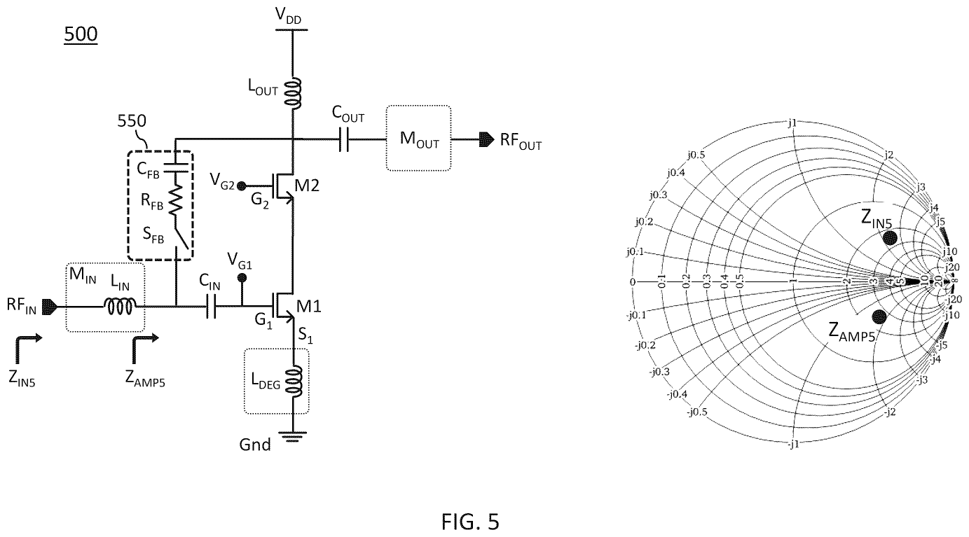

FIG. 5 shows the effect of a feedback network (550, e.g., feedback circuit) on an input impedance (e.g., Z_{AMP5}, Z_{IN5}) of an amplifier (500). The amplifier (500) may be considered as equivalent to the amplifier (300) described above with reference to FIG. 3, with the addition of the feedback network (550) being coupled between the input and the output of the amplifier. In particular, in the configuration shown in FIG. 5, the feedback network (550) is coupled, on one side, between the input match, M_{IN}, and the AC coupling capacitor, C_{IN}, and on the other side, to a node that is common to the inductor, L_{OUT}, and the capacitor, Cour, or in other words, to a drain of the output cascode transistor, M2. As shown in FIG. 5, the feedback network (5500) may include a capacitor, C_{FB}, a resistor, R_{FB}, and a switch, S_{FB}, in series connection. Values of the capacitor, C_{FB}, and the resistor, R_{FB}, may be based on any one or more, of, for example, a frequency of operation, a desired bandwidth, and/or a desired (attenuated) gain, of the amplifier (500).

When the switch, S_{FB}, shown in FIG. 5 is deactivated (e.g., OFF state), the switch, S_{FB}, decouples the input from the output of the amplifier (500), thereby deactivating the feedback (i.e., unaffected amplifier gain). In this case, the feedback network (550) may be considered deactivated and ideally have no, or negligeable/insignificant, effect on the input of the amplifier (500), and therefore on the gain. Accordingly, the input impedances (Z_{AMP5}, Z_{IN5}) of the amplifier (500) may be located according to the Smith chart described above with reference to FIG. 3.

With continued reference to FIG. 5, when the switch, S_{FB}, is activated (e.g., ON state), the switch, S_{FB}, couples the series connected capacitor, C_{FB}, and resistor, R_{FB}, between the input and the output of the amplifier (500), thereby activating the feedback network (550) and any associated attenuation to the gain of the amplifier. The effect of the activated feedback network (550) on the input impedance (e.g., Z_{AMP5}, Z_{IN5}) of the amplifier (500) is shown on the Smith chart of FIG. 5. Such an effect may be considered as being relative an input impedance (Z_{AMP5|D}, Z_{IN5|D}) of the amplifier (500) when the feedback network (550) is deactivated, with (Z_{AMP5|D}, Z_{IN5|D})=(Z_{AMP3}, Z_{IN3}) shown in the Smith chart of FIG. 3.

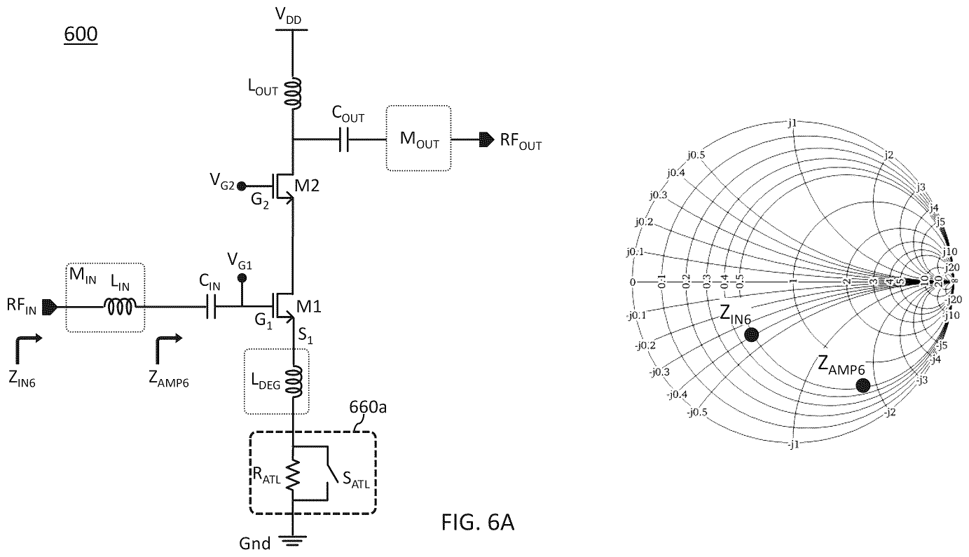

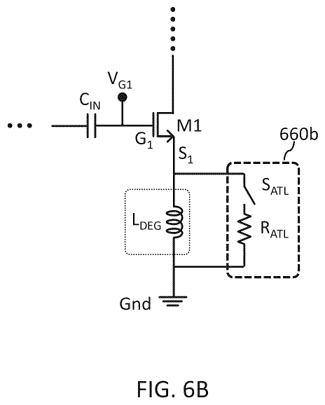

As shown in the Smith chart of FIG. 5, the activated feedback network (550), has the effect of increasing the resistance (e.g., from r=1 to r≈2.5) and the reactance/capacitance (e.g., from j≈−1.5 to j=−2) of the input impedance, Z_{AMP5}, when compared to, Z_{AMP3}, of FIG. 3. Accordingly, as shown in the Smith chart of FIG. 5, the inductor, LIN, used as input match, rotates the impedance, Z_{AMP5}, within the constant resistance circle of r≈2.5 of the Smith chart and therefore results in the impedance, Z_{IN5}, that is not centered at the prime center (e.g., not a perfect match) of the Smith chart. It is noted that the feedback network (550) appears to affect the input impedance of the amplifier in a manner similar to the input attenuator (440), e.g., increasing the resistance and the reactance of the input impedance. However, when paired with another functional block (e.g., 660a/b of FIG. 6A/6B) in order to obtain a target gain state and a target input impedance of the amplifier, because the feedback network (550) goes around the amplifier (e.g., couples amplifier's output to the input), then it may substantially mask an effect on the gain and/or input impedance that the paired functional block (e.g., 660a/b of FIG. 6A/6B) may have in the absence of the feedback. In other words, the interaction of the feedback network (550) with a paired functional block may not result in a suitable control of the gain and input impedance according to the present teachings.

FIG. 6A shows the effect of a deQing circuit (660a) on an input impedance (e.g., Z_{AMP6}, Z_{IN6}) of an amplifier (600). The amplifier (600) may be considered as equivalent to the amplifier (300) described above with reference to FIG. 3, with the addition of the deQing circuit (660a) being coupled to the source of the input transistor, M1. In particular, in the configuration shown in FIG. 6A, the deQing circuit (660a) is coupled to the source, S₁, of the input transistor, M1, through the degeneration inductor, L_{DEG}. In other words, the deQing circuit (660a) and the degeneration inductor, L_{DEG}, may be in series connection between the source, S₁, of the input transistor, M1, and the reference ground, Gnd. As shown in FIG. 6A, the deQing circuit (660a) may include a resistor, R_{ATL}, that is in parallel connection with a switch, S_{ATL}.

As shown in FIG. 6B, in an equivalent embodiment the deQing circuit (660b) may be in parallel connection with the degeneration inductor, L_{DEG}, and therefore directly connected to the source, S₁, of the input transistor, M1. As shown in FIG. 6B, the deQing circuit (660b) may include a resistor, R_{ATL}, that is in series connection with a switch, S_{ATL}. The deQing circuit (660a) of FIG. 6A and (660b) of FIG. 6B may have similar effects on the input impedance (e.g., Z_{AMP6}, Z_{IN6}) of the amplifier (e.g., 600), albeit the effects may be obtained with different values of the resistor, R_{ATL}.

When the switch, S_{ATL}, shown in FIG. 6A/6B is activated/deactivated (e.g., ON/OFF state), the switch, S_{ATL}, removes (e.g., no current flow through) the resistor, R_{ATL}, from the circuit by either a short (e.g., FIG. 6A, low impedance) or an open (e.g., FIG. 6B, high impedance), thereby deactivating a deQing of the degeneration inductor, L_{DEG} (i.e., unaffected amplifier gain). In this case, the deQing circuit (660a, 660b)) may be considered deactivated and ideally have no, or negligeable/insignificant, effect on the input of the amplifier (600), and therefore on the gain. Accordingly, the input impedances (Z_{AMP6}, Z_{IN6}) of the amplifier (600) may be located according to the Smith chart described above with reference to FIG. 3.

With continued reference to FIG. 6A/6B, when the switch, S_{ATL}, is deactivated/activated (e.g., OFF/ON state), the switch, S_{ATL}, couples the resistor, R_{ATL}, to the degeneration inductor, L_{DEG}, thereby activating the deQing of the degeneration attenuation, L_{DEG}, and causing attenuation of the gain of the amplifier (600). The amount of the attenuation provided by the activated deQing circuit (660a, 660b) may be based on the value of the resistor, R_{ATL}. The effect of the activated deQing circuit (660a, 660b) on the input impedance (e.g., Z_{AMP6}, Z_{IN6}) of the amplifier (600) is shown on the Smith chart of FIG. 6A. Such an effect may be considered as being relative to an input impedance (Z_{AMP6|D}, Z_{IN6|D}) of the amplifier (600) when the deQing circuit (660a, 660b) is deactivated, with (Z_{AMP6|D}, Z_{IN6|D})=(Z_{AMP3}, Z_{IN3}) shown in the Smith chart of FIG. 3.

As shown in the Smith chart of FIG. 6A, the activated deQing circuit (660a, 660b), has the effect of decreasing the resistance (e.g., from r=1 to r=0.5) and increasing the reactance/capacitance (e.g., from j≈−1.5 to j=−1.8) of the input impedance, Z_{AMP6}, when compared to, Z_{AMP3}, of FIG. 3. Accordingly, as shown in the Smith chart of FIG. 6A, the inductor, LIN, used as input match, rotates the impedance, Z_{AMP6}, within the constant resistance circle of r=0.5 of the Smith chart and therefore results in the impedance, Z_{IN6}, that is not centered at the prime center (e.g., not a perfect match) of the Smith chart.

Accordingly, when activated, the deQing circuit (660a, 660b) of FIG. 6A/6B may affect the gain of the amplifier (600) primarily by way of the deQing of the degeneration inductor, L_{DEG} (series or parallel, R_{ATL}) per se, but also by way of an undesired secondary effect that changes the input impedance (e.g., Z_{AMP6}, Z_{IN6}), thereby causing a mismatch between the input impedance (e.g., Z_{IN6}) with respect to an impedance of an upstream stage that feeds the amplifier (600). It is noted that as previously described in the present disclosure, the input matching (e.g., M_{IN}) may be assumed fixed since it may not be available for tuning when operating within a same frequency band.

Based on the above description with respect to FIG. 4, FIG. 5, and FIG. 6A/6B, attenuation of the gain of an amplifier based on any one of the functional blocks (440, 550, 660a/660b) may be considered undesirable due to the effect on the input impedance of the amplifier. As such functional blocks may change the input impedance of the amplifier, input matching may be lost, and therefore the gain of the amplifier may be affected by amounts (e.g., error in gain>1 dB) that may not be considered satisfactory in some implementations. Although solutions to such problem may include an amplifier design that does not include such functional blocks, or provision of adjustable input matching based on amplifier gain, these solutions may be considered too restrictive, costly, and/or impractical.

Teachings according to the present disclosure provide a solution that allows design of an amplifier using such functional blocks (e.g., 440, 660a/660b) while maintaining control of the input impedance of the amplifier, therefore of gain. In particular, inventors of the present application have observed that the input attenuator (e.g., 440 of FIG. 4) may have an effect on the input impedance (e.g., Z_{IN3} of FIG. 3) that may be considered as “complementary”, or “opposite”, to an effect the deQing circuit (e.g., 600a/600b of FIG. 6A/6B) may have on the input impedance. Teachings according to the present disclosure take advantage of such complementary/opposite (and independent) effects to counteract one another via concurrent/simultaneous activation of the input attenuator (e.g., 440 of FIG. 4) and the deQing circuit (e.g., 600a/600b of FIG. 6A/6B). Accordingly, a substantially constant input impedance across a plurality of gain states can be maintained. As previously noted in the present disclosure, because the functional block (550) may interact with the functional block (660a/660b), such two blocks may not independently control the input impedance and the gain of the amplifier, and accordingly may not be suitable for achieving a desired target gain state and input impedance.

For example, as described above with reference to FIG. 4, the input attenuator (440) may transform a matched (e.g., purely resistive) input impedance (e.g., Z_{IN3} of FIG. 3) to an impedance (e.g., Z_{IN4} of FIG. 4) having a higher resistance and an inductance, while the deQing circuit (600a/600b) may transform the matched input impedance to an impedance (e.g., Z_{IN6} of FIG. 6A) having a lower resistance and an capacitance. In other words, the input attenuator (440) may be considered as increasing reactance (e.g., toward positive values, more positive) and increasing resistance, while the deQing circuit (600a/600b) may be considered as decreasing reactance (e.g., toward negative values, more negative) and decreasing resistance. In other words, the input attenuator (440) may be considered as increasing inductance (e.g., decreasing capacitance) and increasing resistance, while the deQing circuit (600a/600b) may be considered as increasing capacitance (e.g., decreasing inductance) and decreasing resistance. In other words, the input attenuator (440) may be considered as increasing inductance (e.g., decreasing capacitance) and increasing resistance, while the deQing circuit (600a/600b) may be considered as decreasing inductance (e.g., increasing capacitance) and decreasing resistance. In other words, the input attenuator (440) and the deQing circuit (600a/600b) may be considered as affecting the input impedance in opposite directions (e.g., in the Smith chart).

Based on the above observation, a gain state according to an embodiment of the present disclosure may be provided via a combination of an input attenuator (e.g., 440 of FIG. 4) and a deQing circuit (e.g., 660a/660b of FIG. 6A/6B) that are simultaneously activated. It follows that FIG. 7A shows an amplifier (700) according to the present disclosure including a first transistor, M1. The amplifier (700) comprises a first attenuation block (740, e.g., 440 of FIG. 4) coupled to a first terminal (e.g., the gate, G₁ or a base) of the first transistor, M1, and a second attenuation block (760a, e.g., 660a of FIG. 6A, or 660b of FIG. 6B) coupled to a second terminal (e.g., the source, S₁ or an emitter) of the first transistor, M1. In other words, the amplifier (700) according to the present disclosure includes the input attenuator (740) and the deQing circuit (760a) respective coupled to the gate, G₁ (or base), and the source, S₁ (or emitter), of the first transistor, M1. According to an embodiment of the present disclosure, the amplifier (700A) includes a plurality of gain states, wherein for at least one of the plurality of gain states, the first (740) and second (760a) attenuators are (simultaneously) activated. According to an embodiment of the present disclosure, the amplifier (700A) is configured to operate according to a plurality of frequency bands, wherein at least one frequency band of the plurality of frequency bands includes a plurality of gain states, and wherein during operation according to the at least one frequency band, the first (740) and second (760a) attenuators are (simultaneously) activated for provision of at least one of the plurality of gain states. It is noted that the amplifier (700) may include further functional blocks that may be used to control gain of the amplifier, for example, any one of the (exemplary) functional blocks (210, 220, 225, 230) described above with reference to FIG. 2. In general, it is assumed that such further functional blocks may not influence/change the input impedance of the amplifier (700).

The combined effect of the activated input attenuator (740) and the activated deQing circuit on the input impedance (e.g., Z_{IN7}) of the amplifier (700) is shown on the Smith chart of FIG. 7A. Such an effect may be considered as being based on the effect of the activated input attenuator (740) as described above with reference to the input attenuator (440) of FIG. 4, combined with the effect of the activated deQing circuit (760a) as described above with reference to the deQing circuit (660a/660b). Accordingly, when the input attenuator (740) and the deQing circuit (760a) are deactivated, the input impedance (e.g., Z_{IN7}) of the amplifier (700) may be equal to (the perfect match) Z_{IN3}; when the input attenuator (740) is activated and the deQing circuit (760a) is deactivated, the input impedance (e.g., Z_{IN7}) of the amplifier (700) may be equal to Z_{IN4}; and when the input attenuator (740) is deactivated and the deQing circuit (760a) is activated, the input impedance (e.g., Z_{IN7}) of the amplifier (700) may be equal to Z_{IN6}.

With continued reference to FIG. 7A, when one of the input attenuator (740) or the deQing circuit (760a) is activated, then activation of the other one of the two may transform the input impedance (e.g., Z_{IN7}, now equal to either Z_{IN4} or Z_{IN6}) of the amplifier (700) according to the transformation described above with reference to FIG. 4 and FIG. 6A, e.g., increasing reactance and increasing resistance when the input attenuator (440) is further activated, or decreasing reactance and decreasing resistance when the deQing circuit (760a) is further activated. In other words, as shown in the Smith chart of FIG. 7A, assuming the input attenuator (740) is activated and therefore the input impedance, Z_{IN7}, of the amplifier (700) is equal to Z_{IN4} (i.e., Z_{IN}7=Z_{IN4}), then the further activating of the deQing circuit (760a) may decrease the reactance and increase the resistance of the input impedance, Z_{IN7}, such that, for example, to null the reactance and make the resistance equal to one (i.e., r=1 and therefore Z_{IN}7=Z_{IN3}). In other words, transform the input impedance (e.g., Z_{IN7}) of the amplifier (700) to the desired impedance, Z_{IN3} (e.g., perfect match). Similar description can be provided for the case where the deQing circuit (760a) is assumed activated first, wherein the further activation of the input attenuator (440) increases the reactance and decreases the resistance of the input impedance, Z_{IN7}, to again transform the input impedance (e.g., Z_{IN7}) of the amplifier (700) to the desired impedance, Z_{IN3} (e.g., perfect match).

Although the above description may be considered somewhat intuitive and pictorial, exact values of the resistors (R_{ATT}, R_{ATL}) provided with the first and second attenuation blocks (740, 760a) may be derived by way of readily available circuit simulation algorithms. Such algorithms may help in solving the values of the two resistors (R_{ATT}, R_{ATL}) in view of two constraints: a desired gain/attenuation; and a desired input impedance (e.g., Z_{IN7}). In other words, a system of two equations, Eq1 and Eq2, and two unknowns, r_{ATT} and r_{ATL}, such that:

$$G ( {r}_{ATT} , {r}_{ATL} ) = {G}_{1} ; and \qquad Eq1$$

$${Z}_{IN} ( {r}_{ATT} , {r}_{ATL} ) = {Z}_{IN 3} , \qquad Eq2$$

where a first equation, Eq1, describes a desired/target value, G₁, of the gain/attenuation of the amplifier (700), and a second equation, Eq2, describes a desired/target value, Z_{IN3}, of the input impedance (e.g., Z_{IN7}) of the amplifier (e.g., 700).

It is noted that teachings according to the present disclosure do not limit the desired/target values of the gain and/or of the input impedance of the amplifier (700). Furthermore, for a given gain (e.g., G₁), a number of different combinations for values of the two resistors (R_{ATT}, R_{ATL}) may be provided in view of a number of different targeted values of the input impedance, Z_{IN7}. It is noted that the first equation, Eq1, may be rewritten as the sum of two functions, such that: G(r_{ATT}, r_{ATL})=G′ (r_{ATT})+G″ (r_{ATL})=G₁, each based on one of the two variables (e.g., resistors), r_{ATT} or r_{ATL}. In other words, the gain/attenuation provided by the combination of the first and second attenuation blocks (740, 760a) may be considered as the sum of the attenuations provided by each of the attenuation blocks.

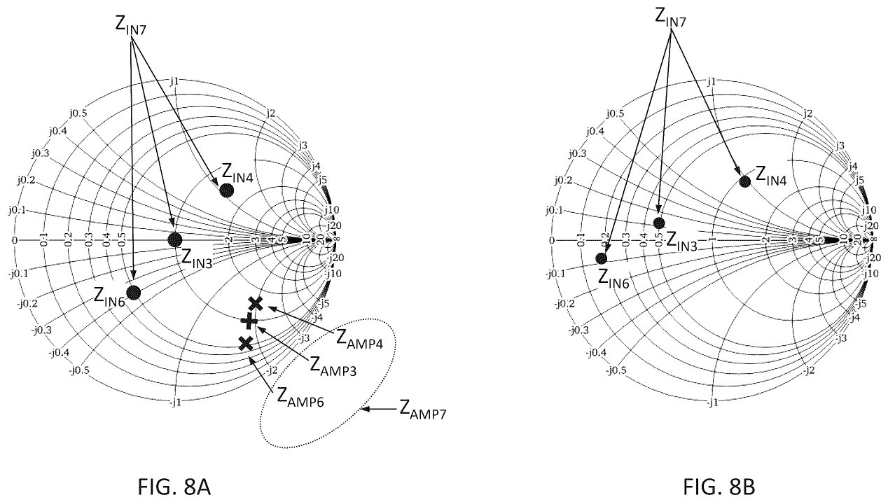

It is noted that teachings according to the present disclosure do not limit the desired/target values of the input impedance, Z_{IN7}, to a purely resistive impedance. In other words, the targeted value, Z_{IN3}, according to the above equation, Eq2, may include a reactive/imaginary component as shown in the Smith chart of FIG. 8B. Accordingly, teachings according to the present disclosure may allow to target any desired input impedance for any given gain state. In other words, the targeted input impedance, Z_{IN3}, according to the above equation, Eq2, can be obtained irrespective of the value (e.g., G₁) of the gain according to the above equation, Eq1. In other words, teachings according to the present disclosure may allow solving the following equations:

$$G ( {r}_{ATT} , {r}_{ATL} ) = {G}_{1 \_ 0} ; \qquad Eq1\_ 0$$

$$G ( {r}_{ATT} , {r}_{ATL} ) = {G}_{1 \_ 1} ; \qquad Eq1\_ 1$$

$$G ( {r}_{ATT} , {r}_{ATL} ) = {G}_{1 \_ 2} ; \qquad Eq1\_ 2$$

$$…$$

$$G ( {r}_{ATT} , {r}_{ATL} ) = {G}_{1 \_k} ; and \qquad Eq1\_k$$

$${Z}_{IN} ( {r}_{ATT} , {r}_{ATL} ) = {Z}_{IN 3} , \qquad Eq2$$

such that for a plurality (e.g., k+1) of different targeted gains, G_{1_0}, G_{1_2}, . . . , G_{1_k}, a constant/same input impedance, Z_{IN3}, is targeted/obtained. In practical implementations, the targeted input impedance, Z_{IN3}, may be based on a best match condition at the input of the amplifier.

As shown in FIG. 7B, according to an embodiment of the present disclosure, the resistors (R_{ATT}, R_{ATL}) provided in the first and second attenuation blocks (740, 760a) of the amplifier (700) may be tunable (e.g., adjustable/settable/programmable) so to allow implementation of different gains/attenuations by way of the (simultaneous) activation of the first and second attenuation blocks (740, 760a). As previously noted in the present disclosure, such different gains/attenuations may be for operation of the amplifier (700) according to a given frequency band, and/or across different frequency bands, including shared across the different frequency bands.

With continued reference to FIG. 7B, according to an embodiment of the present disclosure, the input RF signal, RF_{IN}, may be (time-) shared between the amplifier (700) and a bypass path, P_{BYP}. This may allow selective output, via an output switch, Sour, of an effective RF signal, RF_{EFF}, that may be, in one case, the output RF signal, RF_{OUT}, amplified by the amplifier (700), or in another case, a bypass RF signal, RF_{BYP}, as processed by the bypass path, P_{BYP}. Although not shown in detail, the bypass path, P_{BYP}, may include any one or more RF filters and/or RF attenuators (e.g., similar to attenuators 230 of FIG. 2). In some exemplary embodiments, the bypass path, P_{BYP}, may not include any active elements/circuits for amplification of current. In other words, the bypass path, P_{BYP}, may be a passive path used for attenuation, whereas the amplifier (700) may be considered as including an active path used for amplification (of current).

With continued reference to FIG. 7B, selective coupling of the input RF signal, RF_{IN}, to the bypass path, P_{BYP}, may be provided by a pair of (series) switches (S_{AT1}, S_{BYP}), wherein the switches (S_{AT1}, S_{BYP}) may be used as dual-purpose switches. During an active mode of operation (amplification via the amplifier 700), the switch, S_{AT1}, may be ON to allow coupling of the attenuation block (740) to the amplifier (700), and the switch, S_{BYP}, may be OFF to decouple the amplifier (700) from the bypass path, P_{BYP}. On the other hand, during a passive mode of operation (no amplification via the amplifier 700), the switches, S_{AT1} and S_{BYP}, may be ON to allow coupling of the input RF signal, RF_{IN}, to the bypass path, P_{BYP}. In such passive mode of operation, the attenuation block (740) may be activated or deactivated.

It is noted that although the above description with respect to FIG. 7A, including the equations, Eq1, Eq1_0, . . . , Eq2, refer to the matched input impedance, Z_{IN7}, rather than the cascode input impedance (e.g., Z_{AMP7}), control/derivation of the input impedance according to the present teachings may be equally based on a desired/targeted value of the cascode input impedance, Z_{AMP7}, since, for a given frequency band of operation, the input match, M_{IN}, is assumed fixed/constant, and therefore the two input impedances, Z_{IN7} and Z_{AMP7}, are uniquely related. This is represented in the Smith chart of FIG. 8A.

It is noted that the switches described/shown in the present disclosure, including those described/shown for activation/deactivation of the various described/shown function blocks, may be implemented by way of any suitable design technique, including, for example, techniques using MOSFET transistors, PIN diodes, MEMS switches, or any other suitable switching technology.

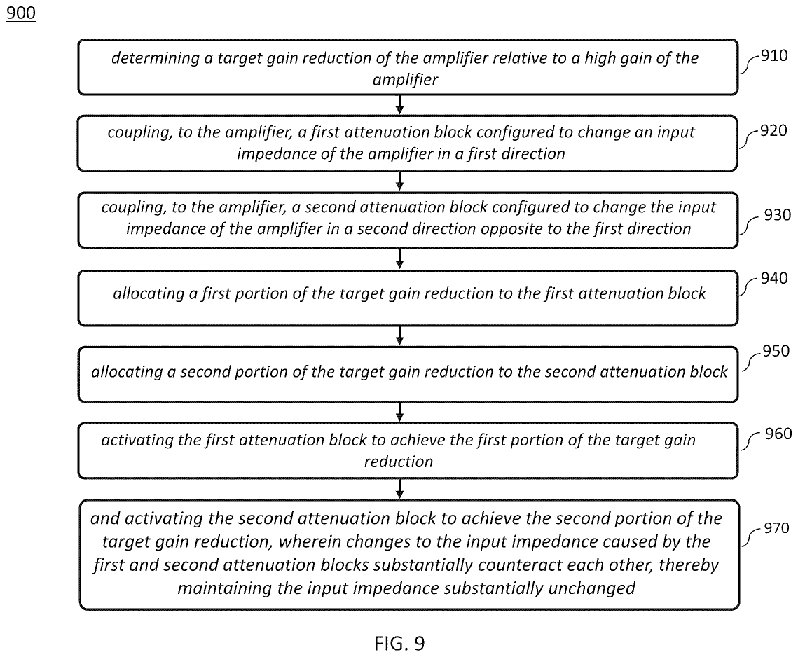

FIG. 9 is a process chart (900) showing various steps of a method according to the present disclosure for controlling gain of an amplifier. As shown in FIG. 9, such steps include: determining a target gain reduction of the amplifier relative to a high gain of the amplifier, according to step (910); coupling, to the amplifier, a first attenuation block configured to change an input impedance of the amplifier in a first direction, according to step (920); coupling, to the amplifier, a second attenuation block configured to change the input impedance of the amplifier in a second direction opposite to the first direction, according to step (930); allocating a first portion of the target gain reduction to the first attenuation block, according to step (940); allocating a second portion of the target gain reduction to the second attenuation block, according to step (950); activating the first attenuation block to achieve the first portion of the target gain reduction, according to step (960); and activating the second attenuation block to achieve the second portion of the target gain reduction, wherein changes to the input impedance caused by the first and second attenuation blocks substantially counteract each other, thereby maintaining the input impedance substantially unchanged, according to step (970).

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

The term “MOSFET” technically refers to metal-oxide-semiconductor-field-effect-transistors; another synonym for MOSFET is “MISFET”, for metal-insulator-semiconductor FET. However, “MOSFET” has become a common label for most types of insulated-gate FETs (“IGFETs”). Despite that, it is well known that the term “metal” in the names MOSFET and MISFET is now often a misnomer because the previously metal gate material is now often a layer of polysilicon (polycrystalline silicon). Similarly, the “oxide” in the name MOSFET can be a misnomer, as different dielectric materials are used with the aim of obtaining strong channels with smaller applied voltages. Accordingly, the term “MOSFET” as used herein is not to be read as literally limited to metal-oxide-semiconductor FETs, but instead includes IGFETs in general.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET and IGFET structures), or in hybrid or discrete circuit forms. Integrated circuit embodiments may be fabricated using any suitable substrates and processes, including but not limited to standard bulk silicon, silicon-on-insulator (SOI), silicon-on-sapphire (SOS), GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS enables low power consumption, the ability to withstand high power signals during operation due to FET stacking, good linearity, and high frequency operation (in excess of about 10 GHz, and particularly above about 20 GHz). Monolithic IC implementation is particularly useful since parasitic capacitances generally can be kept low (or at a minimum, kept uniform across all units, permitting them to be compensated) by careful design.

Voltage levels may be adjusted or voltage and/or logic signal polarities reversed depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functions without significantly altering the functionality of the disclosed circuits.

The examples set forth above are provided to give those of ordinary skill in the art a complete disclosure and description of how to make and use the embodiments of the gate drivers for stacked transistor amplifiers of the disclosure and are not intended to limit the scope of what the applicant considers to be the invention. Such embodiments may be, for example, used within mobile handsets for current communication systems (e.g., WCDMA, LTE, WiFi, etc.) wherein amplification of signals with frequency content of above 100 MHz and at power levels of above 50 mW may be required. The skilled person may find other suitable implementations of the presented embodiments.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a”, “an”, and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

A number of embodiments of the disclosure have been described. Nevertheless, it will be understood that various modifications can be made without departing from the spirit and scope of the present disclosure. Accordingly, other embodiments are within the scope of the following claims.

1. An amplifier circuit, comprising:
a first transistor;
a first attenuation circuit coupled to a first terminal of the first transistor; and
a second attenuation circuit coupled to a second terminal of the first transistor,
wherein the first attenuation circuit, when activated, changes an input impedance of the amplifier in a first direction,
wherein the second attenuation circuit, when activated, changes the input impedance of the amplifier in a second direction that is opposite the first direction, and
wherein the amplifier circuit is configured for operation according to at least:
a first gain state provided by concurrent activation of the first attenuation circuit and the second attenuation circuit, and
a second gain state provided by concurrent deactivation of the first attenuation circuit and the second attenuation circuit, and
wherein an input impedance of the amplifier remains substantially constant during operation according to the first and second gain states.

2. The amplifier circuit of claim 1, wherein:
the first transistor comprises a field-effect-transistor (FET);
the first terminal comprises a gate of the FET; and
the second terminal comprises a source of the FET.

3. The amplifier circuit of claim 2, wherein:
the first attenuation circuit comprises a shunt resistor in series connection with an activation switch.

4. The amplifier circuit of claim 3, wherein:
the shunt resistor comprises an adjustable resistance.

5. The amplifier circuit of claim 3, wherein:
the first attenuation circuit is coupled to the first terminal through a capacitor.

6. The amplifier circuit of claim 3, wherein:
the first attenuation circuit is coupled to the first terminal through an input match circuit.

7. The amplifier circuit of claim 6, wherein:
the input match circuit comprises an inductor in series connection with the gate of the input transistor.

8. The amplifier circuit of claim 1, further comprising:
a degeneration inductor coupled to the second terminal of the first transistor.

9. The amplifier circuit of claim 8, wherein:
the second attenuation circuit is in series connection with the degeneration inductor.

10. The amplifier circuit of claim 9, wherein:
the second attenuation circuit comprises a shunt resistor in parallel connection with an activation switch.

11. The amplifier circuit of claim 10, wherein:
the shunt resistor comprises an adjustable resistance.

12. The amplifier circuit of claim 8, wherein:
the second attenuation circuit is in parallel connection with the degeneration inductor.

13. The amplifier circuit of claim 12, wherein:
the second attenuation circuit comprises a shunt resistor in series connection with an activation switch.

14. The amplifier circuit of claim 1, wherein:
the amplifier circuit is a cascode amplifier comprising an output cascode transistor in series connection with the first transistor.

15. The amplifier circuit of claim 1, wherein:
the amplifier circuit is a single device amplifier.

16. The amplifier circuit of claim 1, wherein:
the amplifier circuit is further configured for operation according to a third gain state provided by concurrent activation of the first attenuation circuit and the second attenuation circuit, and
the input impedance of the amplifier circuit remains substantially constant during operation according to the first, second, and third gain states.

17. The amplifier circuit of claim 16, wherein:
each of the first attenuation circuit and the second attenuation circuit comprise a respective tunable resistor configured to tune a respective attenuation.

18. The amplifier circuit of claim 1, wherein:
the first direction includes increasing a resistance and increasing an inductance of the input impedance, and
the second direction includes decreasing the resistance and decreasing the inductance of the input impedance.

19. The amplifier circuit of claim 1, wherein:
the input impedance is a purely resistive impedance.

20. The amplifier circuit of claim 1, wherein:
the input impedance comprises a non-zero inductance.

21.-28. (canceled)
